(19) United States
(12) Patent Application Publication
(10) Pub. No.: US 2002/0164548 A1
(43) Pub. Date: Nov. 7, 2002

(54) Wet etch compatible deep UV photoresist compositions

(75) Inventors: Sanjay Malik, Attleboro, MA (US); Karin Schlicht, Cumberland, RI (US); Michelle Elderkin, Pawtucket, RI (US); Stefano Volpi, Brasso (Mi) (IT)

Correspondence Address: Paul D. Greeley, Esq., Ohlandt, Greeley, Ruggiero & Perle, L.L.P., 10th Floor, One Landmark Square, Stamford, CT, 06901-2682, US

(73) Assignee: ARCH SPECIALTY CHEMICALS, INC., Norwalk, CT

(21) Appl. No.: 10/076,856

(22) Filed: Feb. 15, 2002

Related U.S. Application Data
(60) Provisional application No. 60/270,465, filed on Feb. 21, 2001.

(51) Int. Cl. G03F 7/032; G03F 7/30

(52) U.S. Cl. 430/323; 430/322; 216/83; 430/905

(57) ABSTRACT

Wet etch processes utilize compatible deep UV photoresist compositions having binder resins that are either:

(A) tertiary-butyl acrylate polymers comprising the monomeric units:

| | | |
|---|---|---|
| 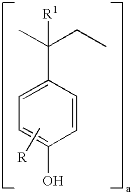 | 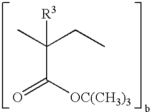 | 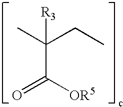 |

where 0.5≦a≦0.7, 0.15≦b≦0.3, 0.1≦c≦0.2, 0.3≦b+c≦0.5; R is H or a C₁-C₄ alkyl group; R¹ is H, methyl or CH₂OR²; each R³ is independently H, methyl, CH₂OR², CH₂CN, CH₂X, or CH₂COOR⁴ where X is Cl, I, Br or F; R² is H or a C₁-C₄ alkyl group; R⁴ is C₁-C₄ alkyl group; R⁵ is an isobornyl, cyclohexyl methyl, cyclohexyl ethyl, benzyl, phenethyl or tetrahydrofurfural group, or

(B) polymers of tertiary-butyl cinnamate that have monomeric units of:

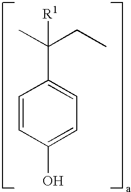

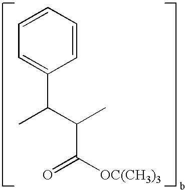

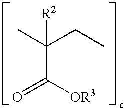

wherein a=0.3 to 0.9, b=0.1 to 0.7, and c=0 to 0.3; R¹ is H, methyl, or CH₂OR⁴; R ⁴ is H or C₁-C₄ alkyl group; R² is H, methyl, CH₂OR⁴, CH₂CN, or CH₂X; X is Cl, I, Br, F, or CH₂COOR⁵; R⁵ is C₁-C₄ alkyl group; and R³ is isobornyl, cyclohexyl methyl, cyclohexyl ethyl, benzyl, or phenethyl.

### FIELD OF THE INVENTION

This invention relates to a lithographic process useful for the production of semiconductor devices. More particularly, the invention pertains to a process using radiation, such as KrF lasers, in combination with a deep UV (DUV) photoresist, e.g., 248 nm or 193 nm photoresist, and a solution of hydrofluoric acid to generate fine patterns on a variety of substrates such as silicon oxide and silicon nitride. The patterns thus formed are transferred into the semi-conductor layer by etching through the oxide or nitride substrate.

### BACKGROUND TO THE INVENTION

Whereas, in the past, dry plasma etching is the preferred method of pattern transfer for deep UV resists, it generally yields vertical profiles. However, the plasma used in the process can cause heavy damage to thin oxide and silicon nitride layers used in Flash memory fabrication. Wet etching is commonly used for transferring pattern through such fragile substrates due to relatively milder conditions employed in these etch processes.

In the early days of the production of integrated circuits, patterned resists masks were used with liquid aqueous etches to remove the underlying regions that had not been masked with resist. There was a deterioration in the lithographically defined dimension caused by undercut of the resist masks by the isotropic character of the liquid etch. For this reason, more expensive reactive ion etching had largely supplanted the earlier method of liquid etching.

However, sometimes it is necessary to mask liquid phase etching of silicon dioxide or doped silicon dioxide. The most convenient way is to use resist to define the region to be etched. However, aqueous solution of hydrofluoric acid can attack the interface between the resist and the oxide layers leading to undercut of the resist even under the best of processing conditions and leading to complete removal and failure of the resist under the worst conditions, where capillary action draws the aqueous solution completely under the resist. If the resist detaches, then all the wafers can be contaminated by resist particles. Etching with conventional, gaseous hydrogen fluoride is also known to penetrate resist, and can lead to even more extensive or enhanced etching under the resist. The aqueous films formed on the surface of this type of gaseous etchings are also subject to capillary action at the interface of the resist and oxide layers.

Although, DUV resists are commonly employed in advanced device manufacturing, the majority of chemically amplified-DUV resists are sensitive to acids hence are not suitable for wet etch processes. One alternative is to use DUV resist for printing patterns on advanced layers and I-Line resist for the layers where wet etching is required. However, mixing two types of tool sets can potentially reduce the throughput and affect the overlay accuracy in the design. It is, therefore, an objective of this invention to provide wet etch compatible DUV resist compositions.

### SUMMARY OF THE INVENTION

It has been discovered that the following polymers have unexpectedly been found to provide wet etch compatible deep UV resist compositions, namely:

(A) tertiary-butyl acrylate polymers comprising the monomeric units:

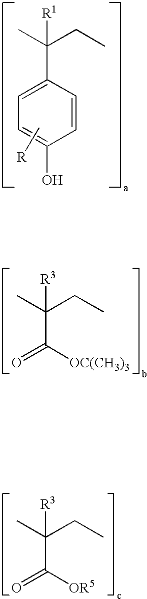

where 0.5≦a≦0.7, 0.15≦b≦0.3, 0.1≦c≦0.2, 0.3≦b+c≦0.5; R is H or a C₁-CH₄ alkyl group; R¹ is H, methyl or CH₂OR²; each R³ is independently H, methyl, CH₂OR², CH₂CN, CH₂X, or CH₂COOR⁴ where X is Cl, I, Br or F; R² is H or a C₁-C₄ alkyl group; R⁴ is C₁-C₄ alkyl group; R⁵ is an isobornyl, cyclohexyl methyl, cyclohexyl ethyl, benzyl, phenethyl or tetrahydrofurfural group, and where preferably, a is from 0.60 to 0.65; b is from 0.20 to 0.25; c is from 0.10 to 0.20; and b+c is from 0.35 to 0.40; R is H, R¹ is H, R² is H; each R³ is independently H or methyl; and R⁵ is an isobornyl group, which polymers are disclosed in the co-pending U.S. patent application No. 09/838,080, filed Apr. 19, 2001, based on U.S. Provisional Application No. 60/ 202132, filed May 5, 2000, both of which are incorporated herein by reference thereto, and

(B) polymers of tertiary-butyl cinnamate that have monomeric units of:

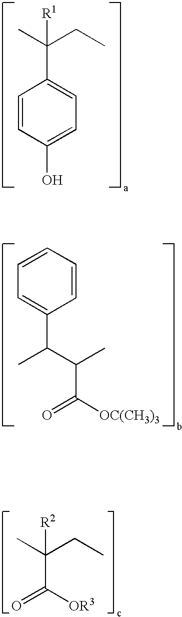

wherein a=0.3 to 0.9, b=0.1 to 0.7, and c=0 to 0.3; R¹ is H, methyl, or CH₂OR⁴; R⁴ is H or C₁-C₄ alkyl group; R² is H, methyl, CH₂OR⁴, CH₂CN, or CH₂X; X is Cl, I, Br, F, or CH₂COOR⁵; R⁵ is C₁-C₄ alkyl group; and R³ is isobornyl, cyclohexyl methyl, cyclohexyl ethyl, benzyl, or phenethyl, which are disclosed in U.S. patent application No. 09/619,180, filed Jul. 19, 2000, now U.S. Pat. No 6,312,870 B1, issued Nov. 6, 2001, which is incorporated herein by reference thereto.

### DETAILED DESCRIPTION OF THE INVENTION

In the tertiary-butyl acrylate polymers, examples of the monomeric unit

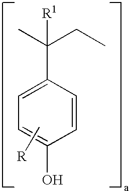

include, but are not limited to, hydroxy styrene and α-methyl hydroxy styrene; examples of the monomeric unit

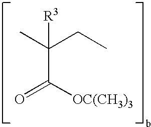

include, but are not limited to, tertiary-butyl acrylate, tertiary-butyl methacrylate, di-tertiary-butyl itaconate, and tertiary-butyl hydroxymethylacrylate; and

examples of the monomeric unit

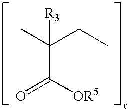

include, but are not limited to, cyclohexyl methyl (meth)acrylate, cyclohexyl ethyl (meth)acrylate, phenethyl (meth)acrylate, benzyl (meth)acrylate, isobornyl (meth)acryl ate and tetrahydrofurfural (meth)acrylate.

The polymer of tertiary-butyl cinnamate may be modified by including a non-alkali solubilizing monomeric unit in the polymer and/or by attaching an acid-labile group such as acetal, tertiary butoxycarbonyl (t-Boc), tetrahydropyranyl esters (THP) or butoxycarbonyl methyl (BocMe) to a portion of the hydroxy groups of the styrene to yield a polymer having the monomeric units:

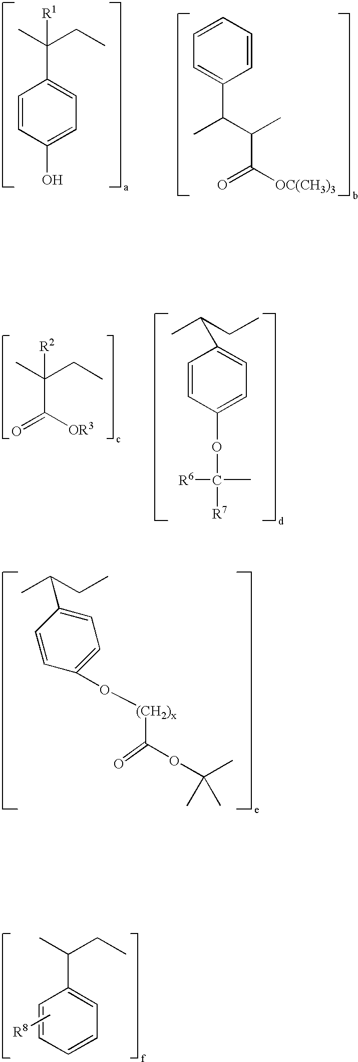

wherein a=0.3 to 0.9, b=0.1 to 0.7, c=0 to 0.3, d=0 to 0.2, e=0 to 0.2, f=0 to 0.2, and a+b+c+d+e+f=1.0; R¹=H, methyl, or CH₂OR⁴; R⁴=H or C1C4 alkyl group; R²=H, methyl, CH₂OR⁴, CH₂CN, or CH₂X; X=Cl, I, Br, F, or CH₂COOR⁵; R⁵=C1-C4 alkyl group; R³=isobornyl, cyclohexyl methyl, cyclohexyl ethyl, benzyl, or phenethyl; R⁶=methyl or ethyl; R⁷=a cyclic or acyclic group selected from a cyclic, bicyclic, linear, or branched alkyl group, halogen substituted alkyl group, aromatic group, substituted aromatic group selected from phenyl, benzyl, phenethyl, naphthyl, or naphthyl ethyl groups which groups optionally contain one or more heteroatoms such as S, O, or N; x is 0 or 1, and R⁸ is H, C1-C4 alkyl group, C1-C4 alkoxy group, or an acetoxy group. Preferably, a=0.3 to 0.7, b=0.1 to 0.7, c=0 to 0.3, d=0 to 0.2, e=0 to 0.2, f=0 to 0.2, and c+d+e+f=0.2 to 0.5.

The non-alkali solubilizing monomer may be, for example, styrene, 3-methyl styrene, tertiary-butyl styrene, acetoxy styrene, methyl(meth)acrylate, isobornyl (meth)acrylate, adamentyl (meth)acrylate, phenyl (meth)acrylate, phenethyl (meth)acrylate, and cyclohexyl acrylate.

In an alternate embodiment, the monomeric unit:

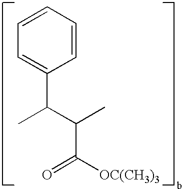

may be replaced with the monomeric unit:

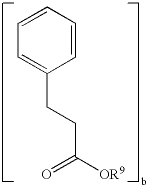

where R⁹ may be any acid-cleavable hydrocarbon group having 1-10 carbon atoms and b is defined as noted above. Examples include, but are not limited to t-amyl, 2,3-dimethyl butyl, 3-methyl pentyl, 2-methyl adamentyl, 2-ethyl adamentyl, methyl cyclohexyl, and methyl cyclopentyl.

The invention is illustrated by, but not limited to, the following examples.

### EXAMPLE 1

### Photoresist Formulation

17.723 g of polymer (hydroxy styrene: 61 mole %, tertiary-butyl acrylate: 25 mole %; isobornyl acrylate 14 mole %; MW: 16,600 daltons; (purchased from TriQuest, LP) was formulated with 0.74 g of triphenylsulfonium 2,4,6-triisopropyl benzenesulfonate (photoacid generator), 0.0185 g of 1,5-diazobicyclo [4.3.0]non-5-ene (acid quencher #1), 0.0185 g of 2,4,5-triphenyl imidazole (acid quencher #2), 0.0179 g of Troysol (leveling agent) and 81.4821 g propylene glycol monomethyl ether acetate (PGMEA) by mixing and stirring all components in amber-colored bottle. Once all components were dissolved, the solution was filtered through 0.2 μm-polytetrafluoroethylene (PTFE) filter into another clean amber colored bottle.

The resist solution was coated onto a 6-inch Si-wafer and softbaked at 140° C. for 60 seconds to obtain a film thickness of 1.0 μm. The softbaked photoresist coated wafers were exposed using 248 nm wavelength light on an ISI XLS 0.53 NA stepper. After completion of exposure, the wafers were subjected to a post exposure bake (PEB) at 140° C. for 60 seconds. Following the PEB, the wafers were puddle developed using a 0.262 N tetramethylammonium hydroxide, aqueous developer. A deionized water rinse was applied for 20 seconds while spinning, followed by spin drying at 3000 rpm.

Wet-etching characteristics of the resist was evaluated by dipping a piece of wafer with imaged patterns into a buffered-hydrofluoric acid solution at 50° C. for 2.5 minutes. The 0.25-μm dense-line features before and after etching treatments were examined under scanning electron microscope. The results indicate no loss of adhesion of the profiles after etching.

### EXAMPLE 2

### Resist A

17.97 g of polymer (hydroxy styrene: 61 mole %, tertiary-butyl acrylate: 25 mole %, isobornyl acrylate 14 mole %, MW: 16,600 daltons (purchased from TriQuest, IP) was formulated with 0.95 g of triphenylsulfonium 2,4,6-triisopropyl benzenesulfonate (photoacid generator), 0.078 g of 1,8-diazabicyclo [5.4.0]undec-7-ene (acid quencher), 0.018 g of Troysol (leveling agent) and 80.98 g propylene glycol monomethyl ether acetate (PGMEA) by mixing and stirring all components in an amber-colored bottle. Once all components were dissolved, the solution was filtered through a 0.2 μm polytetrafluoroethylene (PTFE) filter into another clean amber colored bottle.

### Resist B (Comparative Resist)

Arch 214, an acetal protected polyhydroxy styrene based DUV resist commercially available from Arch Chemicals, Norwalk, Conn.

### Resist C (Comparative Resist)

Arch 8250, an acetal protected polyhydroxy styrene based DUV resist commercially available from Arch Chemicals, Norwalk, Conn.

### Processing

The resist solutions were coated onto 4-inch Si wafers and softbaked at 120° C. (Resist B and C) or at 140° C. (Resist A) for 60 seconds.

The wet-etch characteristics of the resists were evaluated by dipping the wafers into approximately 500 ml of 50:1 aqueous HF solution at room temperature. The attack on the film by the acid was measured by taking before and after film thicknesses.

The results are set forth in Table 1.

TABLE 1

| | | FT before | FT after | | |
|---|---|---|---|---|---|
| | Etch time | HF dip | HF dip | FT loss | Visual |
| Resist | [min] | [A] | [A] | [A] | Observation |
| A | 2.5 | 10069 | 10147 | −78 | No visual |
| A | 5.5 | 10067 | 10157 | −90 | defects |
| A | 12 | 10059 | 10174 | −115 | seen |
| B | 2.5 | 10054 | 9685 | 369 | Pitting |
| B | 6 | 10039 | 8244 | 1795 | |
| B | 10 | 10060 | 8297 | 1763 | |
| C | 2.5 | 10087 | 8253 | 1834 | Severe |
| C | 5 | 10061 | 9101 | 960 | pitting |
| C | 10 | 9672 | 8666 | 1006 | |

As can be seen from the above Table 1, Resist A does not show any film loss after HF treatment while Resists B and C exhibit severe film loss. This is an important criteria. If the resist film is attacked during the wet etch process, this will result in resist line width change during etch and subsequently poor pattern transfer.

While the invention has been described herein with reference to the specific embodiments thereof, it will be appreciated that changes, modification and variations can be made without departing from the spirit and scope of the inventive concept disclosed herein. Accordingly, it is intended to embrace all such changes, modification and variations that fall with the spirit and scope of the appended claims.

We claim:

1. In a process for wet etch pattern transfer from a deep UV photoresist to a substrate by use of a wet etchant, the improvement comprising employing as the deep UV photoresist on the substrate a photoresist coating from a radiation-sensitive composition comprising a binder resin, a photoacid generator, and a solvent for the binder resin and photoacid generator, wherein the binder resin comprises a polymer of the radiation-sensitive composition is selected from the groups consisting of:
(A) a tertiary-butyl acrylate polymer comprising the monomeric units: 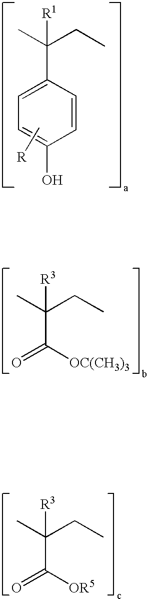
where 0.5≦a≦0.7, 0.15≦b≦0.3, 0.1≦c≦0.2, 0.3≦b+c≦0.5; R is H or a C₁-C₄ alkyl group; R¹ is selected from the group consisting of H, methyl or CH₂OR²; each R³ is independently selected from the group consisting of H, methyl, CH₂OR², CH₂CN, CH₂X, or CH₂COOR⁴ where X is selected from the group consisting of Cl, I, Br or F; R² is selected from the group consisting of H or a C₁-C₄ alkyl group; R⁴ is selected from the group consisting of C₁-C₄ alkyl group; and R⁵ is selected from the group consisting of an isobornyl, cyclohexyl methyl, cyclohexyl ethyl, benzyl, phenethyl or tetrahydrofurfural group, and
(B) a polymer of tertiary-butyl cinnamate that has monomeric units of: 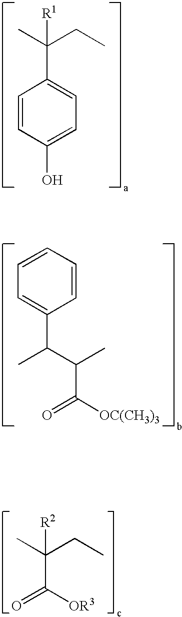
wherein a=0.3 to 0.9, b=0.1 to 0.7, and c=0 to 0.3; R¹ is selected from the group consisting of H, methyl, or CH₂OR⁴; R⁴ is selected from the group consisting of H or C₁-C₄ alkyl group; R² is selected from the group consisting of H, methyl, CH₂OR⁴, CH₂CN, or CH₂X; X is selected from the group consisting of Cl, I, Br, F, or CH₂COOR⁵; R⁵ is selected from the group consisting of C₁-C₄ alkyl group; and R³ is selected from the group consisting of isobornyl, cyclohexyl methyl, cyclohexyl ethyl, benzyl, or phenethyl.

2. A process according to claim 1 wherein the binder polymer is a tertiaty-butyl acrylate polymer wherein a is from 0.60 to 0.65; b is from 0.20 to 0.25; c is from 0.10 to 0.20; and b+c is from 0.35 to 0.40; R is H; R¹ is H; each R³ is independently selected from the group consisting of H or methyl; and R5 is an isobornyl group.

3. A process according to claim 1 wherein the binder polymer is a tertiary-butyl acrylate polymer wherein the monomeric unit 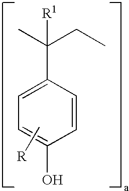
is selected from the group consisting of hydroxy styrene and α-methyl hydroxy styrene;
the monomeric unit 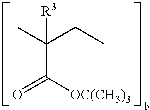
is selected from the group consisting of tertiary-butyl acrylate, tertiary-butyl methacrylate, di-tertiary-butyl itaconate, and tertiary-butyl hydroxymethylacrylate; and
the monomeric unit 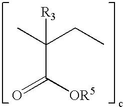
is selected from the group consisting of cyclohexyl methyl (meth)acrylate, cyclohexyl ethyl (meth)acrylate, phenethyl (meth)acrylate, benzyl (meth)acrylate, isobornyl (meth)acrylate and tetrahydrofurfural (meth)acrylate.

4. A process according to claim 3 wherein the binder resin is a polymer of hydroxy styrene, tertiary-butyl acrylate and isobornyl acrylate monomeric units

5. A process according to claim 4 wherein the photoacid generator is triphenylsulfonium 2,4,6-triisopropyl benzenesulfonate and the solvent is propylene glycol monomethyl ether acetate.

6. A process according to claim 1 wherein the wet etchant comprises a hydrofluoric acid solution.

7. A process according to claim 4 wherein the wet etchant comprises a hydrofluoric acid solution.

8. A process according to claim 5 wherein the wet etchant comprises a hydrofluoric acid solution.

9. A wet etch patterned substrate when produced according to the process of claim 1.

10. A wet etch patterned substrate when produced according to the process of claim 2

11. A wet etch patterned substrate when produced according to the process of claim 3.

12. A wet etch patterned substrate when produced according to the process of claim 4.

13. A wet etch patterned substrate when produced according to the process of claim 5.

14. A wet etch patterned substrate when produced according to the process of claim 6.

15. A wet etch patterned substrate when produced according to the process of claim 7.

16. A wet etch patterned substrate when produced according to the process of claim 8.

17. A method for forming a pattern comprising the steps of:
(1) coating a semiconductor substrate with radiation-sensitive photoresist composition comprising a polymer binder resin, a photoacid generator, and a solvent for the binder resin and photoacid generator, wherein the binder resin is a polymer selected from the group consisting of:
(A) a tertiary-butyl acrylate polymer comprising the monomeric units: 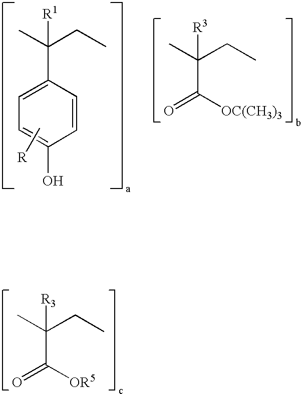
where 0.5≦a≦0.7, 0.15≦b≦0.3, 0.1≦c≦0.2, 0.3≦b+c≦0.5; R is H or a C₁-C₄ alkyl group; R¹ is selected from the group consisting of H, methyl or CH₂OR²; each R³ is independently selected from the group consisting of H, methyl, CH₂OR², CH₂CN, CH₂X, or CH₂COOR⁴ where X is selected from the group consisting of Cl, I, Br or F; R² is selected from the group consisting of H or a C₁-C₄ alkyl group; R⁴ is selected from the group consisting of C₁-C₄ alkyl group; and R⁵ is selected from the group consisting of an isobornyl, cyclohexyl methyl, cyclohexyl ethyl, benzyl, phenethyl or tetrahydrofurfural group, and
(B) a polymer of tertiary-butyl cinnamate that has monomeric units of: 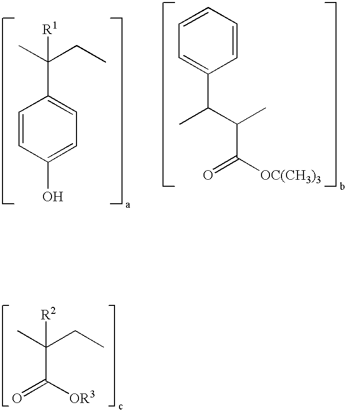
wherein a=0.3 to 0.9, b=0.1 to 0.7, and c=0 to 0.3; R¹ is selected from the group consisting of H, methyl, or CH₂OR⁴; R⁴ is selected from the group consisting of H or C₁-C₄ alkyl group; R² is selected from the group consisting of H, methyl, CH₂OR⁴, CH₂CN, or CH₂X; X is selected from the group consisting of Cl, I, Br, F, or CH₂COOR⁵; R⁵ is selected from the group consisting of C₁-C₄ alkyl group; and R³ is selected from the group consisting of isobornyl, cyclohexyl methyl, cyclohexyl ethyl, benzyl, or phenethyl;
(2) forming a resist pattern on the semiconductor substrate by exposing the photoresist coating to deep UV radiation and contacting the exposed photoresist coating to a developer to expose a portion of the photoresist substrate; and
(3) wet etching said exposed portion of said semiconductor substrate with a wet etchant by using the resist pattern as an etching mask.

18. A method according to claim 17 wherein the binder polymer is a tertiary-butyl acrylate polymer wherein the monomeric unit 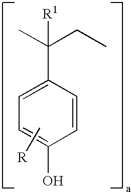
is selected from the group consisting of hydroxy styrene and α-methyl hydroxy styrene;
the monomeric unit 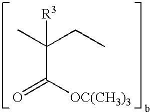
is selected from the group consisting of tertiary-butyl acrylate, tertiary-butyl methacrylate, di-tertiary-butyl itaconate, and tertiary-butyl hydroxymethylacrylate; and
the monomeric unit 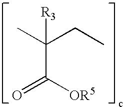
is selected from the group consisting of cyclohexyl methyl (meth)acrylate, cyclohexyl ethyl (meth)acrylate, phenethyl (meth)acrylate, benzyl (meth)acrylate, isobornyl (meth)acrylate and tetrahydrofurfural (meth)acrylate.

19. A method according to claim 18 wherein the binder resin is a polymer of hydroxy styrene, tertiary-butyl acrylate and isobornyl acrylate monomeric units

20. A method according to claim 19 wherein the photoacid generator is triphenylsulfonium 2,4,6-triisopropyl benzenesulfonate, the solvent is propylene glycol monomethyl ether acetate, and the wet etchant comprises a hydrofluoric acid solution.
